(19) United States
(12) Patent Application Publication
(10) Pub. No.: US 2022/0399264 A1
(43) Pub. Date: Dec. 15, 2022

(54) INTERCONNECTION STRUCTURE FOR INTEGRATED CIRCUIT PACKAGE AND THE METHOD THEREOF

(71) Applicant: Monolithic Power Systems, Inc., San Jose, CA (US)

(72) Inventors: Yi Sun, Saratoga, CA (US); Heng Yang, San Jose, CA (US); Deming Xiao, Los Altos Hills, CA (US)

(21) Appl. No.: 17/343,942

(22) Filed: Jun. 10, 2021

(51) Int. Cl. H01L 23/50; G05F 1/56; H01L 23/498; H01L 23/00

(52) U.S. Cl. CPC H01L 23/50; G05F 1/56; H01L 23/49816; H01L 24/14; H01L 2224/90; H01L 2224/72

(57) ABSTRACT

An interconnection structure for IC package onto the external device is discussed. The IC package has a voltage regulator contained therein; and the external device has a load assembled thereupon. A plurality of connection devices with elasticity are attached to the IC package, so that when a perpendicular force is applied to the connection devices, the IC package is electrically coupled to the external device to provide power supply to the load with ease replacement.

### FIELD

The present invention relates to electronic circuits, more specifically, the present invention relates to interconnection structure for integrated circuit package and the method thereof.

### BACKGROUND

Voltage regulators in the form of integrated circuit (IC) chip and/or module are widely applied to provide power supply for central processing units (CPU), graphics processing units (GPU), field-programmable gate arrays (FPGA), application-specific integrated circuits (ASIC), and etc. Typically, the IC chip and/or the module in which a voltage regulator is contained is soldered on a printed board circuit (PCB) outside of a socket in which a load (e.g. the CPU, GPU, FPGA, ASIC and etc.) is installed. However, a rework process that involves de-soldering and re-soldering is necessary to replace a damaged and/or faulty voltage regulator. The rework process for replacing a faulty voltage regulator is costly and time consuming. Further, the voltage regulator that is soldered outside of the socket of the load (e.g. a CPU) have to deliver its power to the load through PCB traces and socket connections, which adds large parasitic elements (e.g. parasitic resistance and inductance) to the power distribution network (PDN). The extra parasitic elements slow down the voltage regulator's response to a dynamic load current, creating voltage deviation and oscillation on the load. The undesired voltage deviation and oscillation can cause the load to malfunction.

### SUMMARY

It is an object of the present invention to provide an improved interconnection structure, which solves the above problems.

In accomplishing the above and other objects, there has been provided, in accordance with an embodiment of the present invention, an interconnection structure, comprising: an IC package, in which a voltage regulator is contained; and a plurality of connection devices with elasticity, configured to be attached to the IC package, wherein the IC package is electrically coupled to an external device via the connection devices when the connection devices are compressed, so as to have the voltage regulator provide power supply to a load assembled on the external device.

In addition, there has been provided, in accordance with an embodiment of the present invention, an interconnection structure, comprising: an IC package, in which a voltage regulator is contained; an interposer, having a first surface and a second surface, respectively having a plurality of up electrical pads and a plurality of bottom electrical pads formed thereupon, the up electrical pads being electrically coupled to the IC package, and a plurality of connection devices with elasticity, configured to be attached to the bottom electrical pads.

Furthermore, there has been provided, in accordance with an embodiment of the present invention, an interconnection method between an IC package and an external device, comprising: attaching a plurality of connection devices with elasticity to the IC package, the IC package having a voltage regulator contained therein; and compressing the connection devices to have the IC package be electrically coupled to the external device, so as to have the voltage regulator provide power supply to a load placed on the external device.

### BRIEF DESCRIPTION OF THE DRAWINGS

FIG. 1A schematically shows an interconnection structure 100a in accordance with an embodiment of the present invention.

FIG. 1B schematically shows an interconnection structure 100b in accordance with an embodiment of the present invention.

FIG. 2A schematically shows an interconnection structure 200a in accordance with an embodiment of the present invention.

FIG. 2B schematically shows an interconnection structure 200b in accordance with an embodiment of the present invention.

FIG. 2C schematically shows an interconnection structure 200c in accordance with an embodiment of the present invention.

FIG. 3 schematically shows an interconnection structure 300 in accordance with an embodiment of the present invention.

FIG. 4 schematically shows an interconnection structure 400 in accordance with an embodiment of the present invention.

FIG. 5 schematically shows an interconnection structure 500 in accordance with an embodiment of the present invention.

FIG. 6 schematically shows an interconnection structure 600 in accordance with an embodiment of the present invention.

FIG. 7 schematically shows a top view of an interconnection structure 700 in accordance with an embodiment of the present invention.

FIG. 8 schematically shows a flowchart 800 of an interconnection method between an IC package and an external device in accordance with an embodiment of the present invention.

The use of the similar reference label in different drawings indicates the same of like components.

### DETAILED DESCRIPTION

Embodiments of circuits for interconnection structure are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

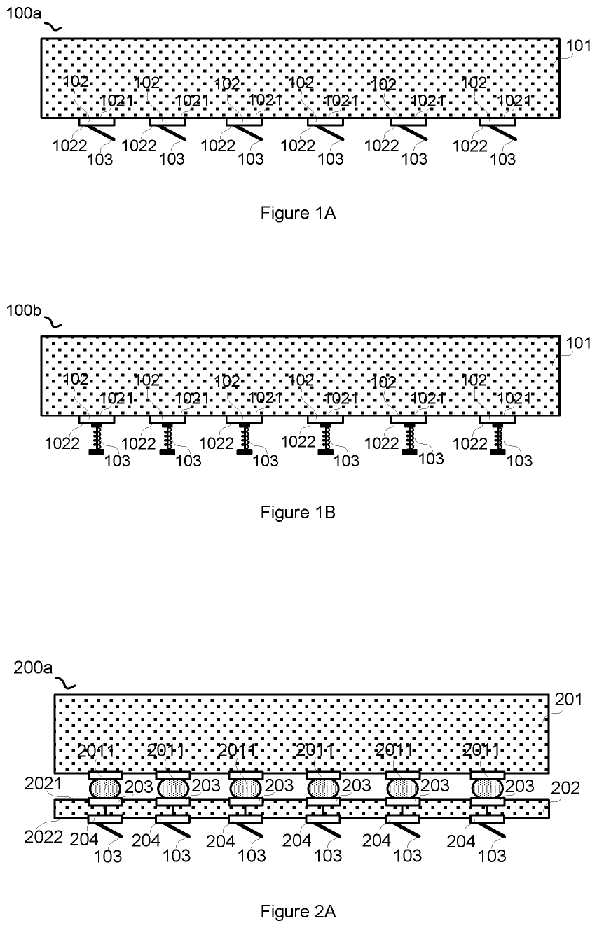

FIG. 1A schematically shows an interconnection structure 100a in accordance with an embodiment of the present invention. In the example of FIG. 1A, the interconnection structure 100a comprises: an IC package 101, in which a voltage regulator is contained; and a plurality of connection devices 103 with elasticity, attached to the IC package 101.

In one embodiment of the present invention, the interconnection structure 100a may have a plurality of electrical (e.g. metal) pads 102, and the connection devices 103 are attached to the IC package 101 by way of the electrical pads 102.

In one embodiment of the present invention, the IC package 101 may comprise an IC chip. In other embodiments of the present invention, the IC package 101 may comprise a module, which may also include passive components such as inductor, capacitor, and/or other components placed beside the IC chip.

In one embodiment of the present invention, the connection device 103 may comprise a connection clip, e.g., a metal spring clip. In another embodiment of the present invention, the connection device 103 may comprise a spring pin, as shown in FIG. 1B.

In one embodiment of the present invention, the voltage regulator may comprise a DC-DC converter operable to provide a desired voltage level (i.e. power supply) to the load.

In one embodiment of the present invention, the IC package 101 comprises a traditional IC package, which may have ball grid array (BGA), or land grid array (LGA), or quad flat no-leads package (QFN), or chip scale package (CSP), etc., formed on a bottom surface of the IC package, and the connection clip 103 may be electrically coupled to the IC package via an interposer.

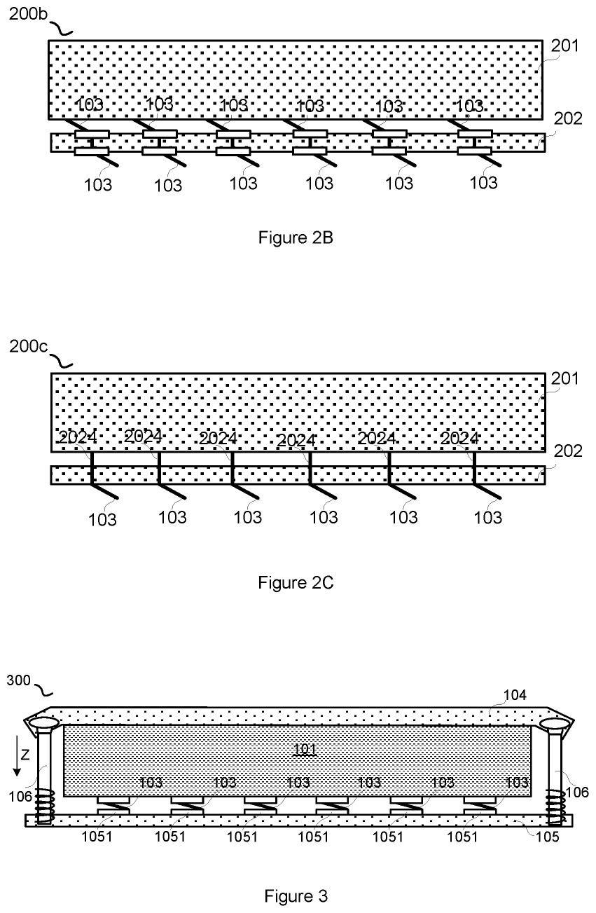

FIG. 2A schematically shows an interconnection structure 200a in accordance with an embodiment of the present invention. In the example of FIG. 2A, the interconnection structure 200a comprises: an IC package 201 having a bottom surface on which a plurality of BGA 2011 is formed on; and an interpose 202, having a first surface and a second surface, respectively having a plurality of up electrical pads 203 and a plurality of bottom electrical pads 204 formed thereupon, each of the up electrical pads 203 being electrically coupled to a corresponding BGA of the IC package 201, and each of the bottom electrical pads 204 having a connection device 103 with elasticity attached thereto.

Inside the interposer 202, each of the up electrical pads 203 is electrically coupled to a corresponding bottom electrical pad 204.

In one embodiment of the present invention, the number of the up electrical pad 203 is same as the number of the bottom electrical pad 204; and the number of BGA 2011 is equal to or lower than the number of the up electrical pad 203.

In one embodiment of the present invention, the interposer 202 may have no electrical pad formed on the first surface, e.g., the interposer 202 may have no up electrical pads 203 formed thereon. In another embodiment of the present invention, the interposer 202 may have no electrical pad formed on either surface.

FIG. 2B schematically shows an interconnection structure 200b in accordance with an embodiment of the present invention. In the example of FIG. 2B, the interconnection structure 200b comprises: an IC package 201, having a voltage regulator contained therein; and an interposer 202, having a first surface and a second surface, respectively having a plurality of connection devices 103 with elasticity attached thereto. The connection devices 103 are compressed by a force application device, so that the IC package 201 is electrically coupled to the interposer 202, and the interposer 202 is electrically coupled to an external device (e.g. a printed circuit board, or a socket), to have the voltage regulator contained in the IC package provide power supply to a load assembled on the external device.

In on embodiment of the present invention, the first surface and the second surface of the interposer 202 is opposite to each other. Inside the interposer 202, each of the connection devices 103 at the first surface is electrically coupled to a corresponding connection device 103 at the second surface.

FIG. 2C schematically shows an interconnection structure 200c in accordance with an embodiment of the present invention. In the example of FIG. 2C, the interconnection structure 200c comprises: an IC package 201, having a voltage regulator contained therein; and an interposer 202, having a plurality of connection devices 103 with elasticity attached thereto. The interposer 202 is electrically coupled to the IC package 201 by way of a plurality of metal contacts (e.g., metal needles). The connection devices 103 are compressed by a force application device, so that the IC package 201 is electrically coupled to an external device (e.g. a printed circuit board, or a socket) by way of the interposer 202, to have the voltage regulator contained in the IC package provide power supply to a load assembled on the external device.

FIG. 3 schematically shows an interconnection structure 300 in accordance with an embodiment of the present invention. In the example of FIG. 3, the interconnection structure 300 comprises: the IC package 101, in which a voltage regulator is contained; and a force application device 104, configured to apply a force on the IC package 101, to compress the connection devices 103, to have the IC package 101 be electrically coupled to a printed circuit board 105 via the connection devices.

In one embodiment of the present invention, the printed circuit board 105 having a plurality of electrical pads 1051 formed thereon; and the IC package 101 is coupled to the printed circuit board 105 via the connection devices and the electrical pads 1051.

In one embodiment of the present invention, the force application device 104 is assembled on the printed circuit board 105 by way of screws 106.

In one embodiment of the present invention, the connection devices 103 are electro-mechanical coupled to the corresponding electrical pads 1051.

In one embodiment of the present invention, the force applied by the force application device 104 is perpendicular with the PCB plane. That is, the applied force has a Z direction (i.e. vertical direction) as shown in FIG. 3.

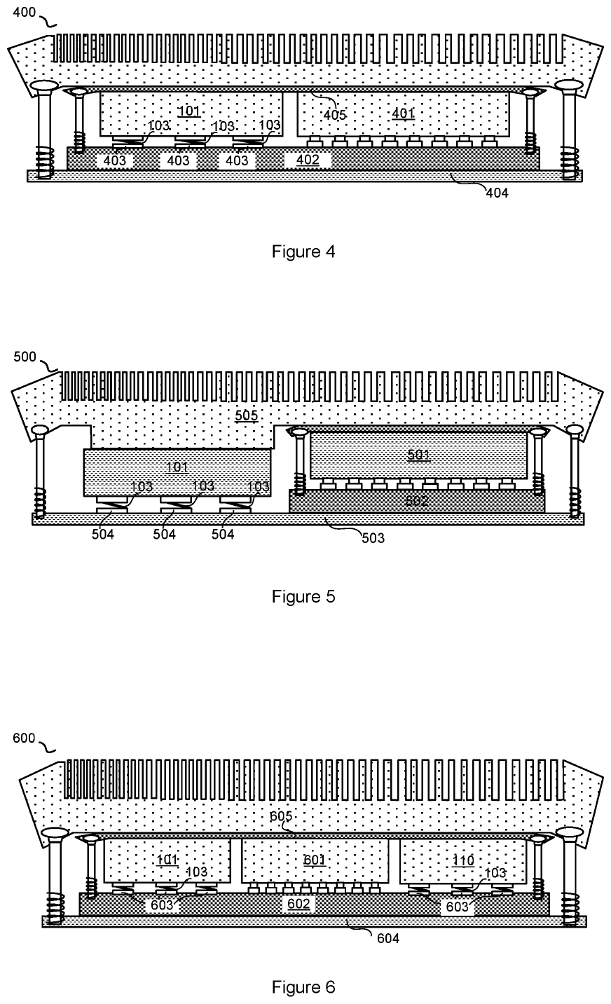

In one embodiment of the present invention, a socket on which a load (e.g. the CPU, GPU, FPGA, ASIC and etc.) is assembled is also placed on the print circuit board 105. The IC package 101 may be placed on the socket next to the load (refer to FIG. 4), or the IC package 101 may be placed on the printed circuit board 105 outside the socket but next to the socket (refer to FIG. 5).

FIG. 4 schematically shows an interconnection structure 400 in accordance with an embodiment of the present invention. In the example of FIG. 4, the interconnection structure 400 comprises: an IC package 101, in which a voltage regulator is contained, the IC package 101 having a plurality of connection devices 103 with elasticity attached thereto; a load 401, configured to be powered by a voltage supply from the voltage regulator; and a socket 402, on which the load 401 is assembled.

In one embodiment of the present invention, the socket 402 may have a plurality of electrical (e.g. metal) pads 403, and each of the electrical pad 403 is electrically coupled to a corresponding connection device 103 when a force is applied to the connection devices 103.

In one embodiment of the present invention, the socket 402 has a lid 405, which acts as a force application device to apply a force (e.g., a perpendicular force) to compress the connection devices 103. In other embodiments of the present invention, the force application device may include other devices such as heat sink, or dedicated cover.

In one embodiment of the present invention, the socket 402 may be placed on a printed circuit board 404.

FIG. 5 schematically shows an interconnection structure 500 in accordance with an embodiment of the present invention. In the example of FIG. 5, the interconnection structure 500 comprises: an IC package 101, in which a voltage regulator is contained, the IC package 101 having a plurality of connection devices 103 with elasticity attached thereto; a load 501, configured to be powered by the voltage regulator; a socket 502, on which the load 501 is assembled; and a printed circuit board 503, on which the socket 502 is placed, the printed circuit board 503 having a plurality of electrical (e.g. metal) pads 504, each of the electrical pad 504 being electrically coupled to a corresponding connection device 103 when a force is applied to the connection clips 103.

In one embodiment of the present invention, the interconnection structure 500 further comprises: a force application device 505, configured to apply a force on the IC package 101 to compress the connection device 103 and have the connection devices 103 electrically coupled to the printed circuit board 503 via the electrical pads 504.

In one embodiment of the present invention, more than one voltage regulators may be needed to provide power supply to the load. FIG. 6 schematically shows an interconnection structure 600 that contains more than one voltage regulators in accordance with an embodiment of the present invention. In the example of FIG. 6, the interconnection structure 600 comprises: a first IC package 101 and a second IC package 110, each having a voltage regulator contained therein, and each having a plurality of connection devices 103 with elasticity attached thereto; a load 601, configured to be powered by the voltage regulators; a socket 602, on which the load 601 is assembled, the socket 602 having a plurality of electrical (e.g. metal) pads 603, each of the electrical pads 603 being electrically coupled to a corresponding connection clip 103 when a force is applied to the connection clips 103.

In one embodiment of the present invention, the socket 602 has a lid 605, which acts as a force application device to apply a force (e.g., a perpendicular force) to compress the connection devices 103, to have the IC packages 101 and 110 electrically coupled to the socket 602. In other embodiments of the present invention, the force application devices may have other devices such as heat sink, or dedicated cover.

In one embodiment of the present invention, the socket 602 may be placed on a printed circuit board 604.

FIG. 6 is cross-section view of the interconnection structure, which shows two IC packages. However, from the top view, the interconnection structure may have more than two IC packages.

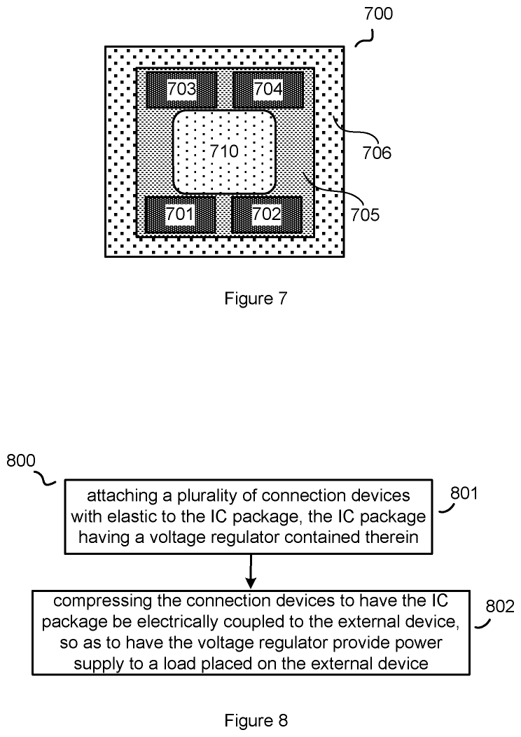

FIG. 7 schematically shows a top view of an interconnection structure 700 in accordance with an embodiment of the present invention. As shown in FIG. 7, the interconnection structure 700 has four IC packages 701, 702, 703 and 704 assembled on a socket 705, which is on a printed circuit board 706. The four IC packages are placed around and next to the load 710.

FIG. 8 schematically shows a flowchart 800 of an interconnection method between an IC package and an external device in accordance with an embodiment of the present invention. The method comprising:

Step 801: attaching a plurality of connection devices with elasticity to the IC package, the IC package having a voltage regulator contained therein. And

Step 802, compressing the connection devices to have the IC package be electrically coupled to the external device, so as to have the voltage regulator provide power supply to a load placed on the external device.

In one embodiment of the present invention, the connection devices are attached to the IC package via an interposer.

In one embodiment of the present invention, the external device comprises a printed circuit board, and the load is placed on the printed circuit board via a socket.

In one embodiment of the present invention, the external device comprises a socket placing on a printed circuit board; and the load is assembled on the socket.

In one embodiment of the present invention, the compressing is performed by a socket lid, a heat sink or a dedicated cover.

In one embodiment, the connection device comprises a spring pin (e.g., a pogo pin), or a metal spring clip.

Several embodiments of the foregoing interconnection structure provide easy replacement for power supply and/or power supply modules. Unlike the conventional technology, several embodiments of the foregoing interconnection structure adopt connection device with elasticity to electrically couple the IC package to the socket and/or to the printed circuit board, which eliminates the de-soldering and soldering process for IC chip and/or module installation and re-work, thus reducing the risk, time and the cost associated with the soldering and de-soldering process. In addition, the IC package (i.e., the voltage regulators) may be placed on the same socket next to the load (e.g., CPU, GPU, FPGA, ASIC, etc.), which eliminates the parasitic element introduced by the PCB traces and socket connections in the power distribution network (PDC), thus improving the speed of the dynamic response of the voltage regulator and the performance of its load (e.g. CPU).

It is to be understood in these letters patent that the meaning of “A” is coupled to “B” is that either A and B are connected to each other as described below, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

This written description uses examples to disclose the invention, including the best mode, and also to enable a person skilled in the art to make and use the invention. The patentable scope of the invention may include other examples that occur to those skilled in the art.

What is claimed is:

1. An interconnection structure, comprising:
an IC package, in which a voltage regulator is contained; and
a plurality of connection devices with elasticity, configured to be attached to the IC package, wherein the IC package is electrically coupled to an external device via the connection devices when the connection devices are compressed, so as to have the voltage regulator provide power supply to a load assembled on the external device.

2. The interconnection structure of claim 1, wherein:
the external device comprises a printed circuit board;
the load is assembled on a socket placed on the printed circuit board; and
the IC package is placed next to the socket.

3. The interconnection structure of claim 1, wherein:
the external device comprises a socket placed on a printed circuit board.

4. The interconnection structure of claim 1, further comprising:
an interposer, wherein the connection devices are attached to the interposer, and wherein the IC package is electrically coupled to the external device via the interposer and the connection devices.

5. The interconnection structure of claim 1, wherein:
the connection device comprises a metal spring clip or a spring pin.

6. The interconnection structure of claim 1, wherein:
the connection devices are compressed by a force applicable device.

7. The interconnection structure of claim 1, wherein:
the external device having a plurality of electrical pads formed thereupon; and
the connection devices are electrically coupled to corresponding electrical pad when compressed.

8. An interconnection structure, comprising:
an IC package, in which a voltage regulator is contained;
an interposer, having a first surface and a second surface, respectively having a plurality of up electrical pads and a plurality of bottom electrical pads formed thereupon, the up electrical pads being electrically coupled to the IC package; and
a plurality of connection devices with elasticity, configured to be attached to the bottom electrical pads.

9. The interconnection structure of claim 8, further comprising:
a force application device, configured to apply a force on the IC package to compress the connection devices, to have the IC package and the interposer be electrically coupled to an external device via the connection devices, and provide power supply to a load assembled on the external device.

10. The interconnection structure of claim 9, wherein:
the external device comprises a printed circuit board, and wherein the load is assembled on the printed circuit board via a socket.

11. The interconnection structure of claim 9, wherein:
the external device comprises a socket placed on a printed circuit board; and
the force application device comprises a socket lid.

12. The interconnection structure of claim 8, wherein:
the connection device comprises a metal spring clip or a spring pin.

13. The interconnection structure of claim 8, wherein:
each of the up electrical pads is electrically coupled to a corresponding bottom electrical pad inside the interposer.

14. The interconnection structure of claim 8, wherein:
the IC package has ball grid array package, or land grid array package, or quad flat no-leads package, or chip scale package.

15. An interconnection method between an IC package and an external device, comprising:
attaching a plurality of connection devices with elasticity to the IC package, the IC package having a voltage regulator contained therein; and
compressing the connection devices to have the IC package be electrically coupled to the external device, so as to have the voltage regulator provide power supply to a load placed on the external device.

16. The interconnection method of claim 15, wherein:
the compressing is performed by a socket lid, a heat sink or a dedicated cover.

17. The interconnection method of claim 15, wherein:
the connection device comprises a spring pin, or a metal spring clip.

18. The interconnection method of claim 15, wherein:
the external device comprises a printed circuit board, and wherein the load is assembled on the printed circuit board via a socket.

19. The interconnection method of claim 15, wherein:
the external device comprises a printed circuit board, and the load is placed on the printed circuit board via a socket.
